(19) United States
(12) Patent Application Publication
(10) Pub. No.: US 2023/0031398 A1
(43) Pub. Date: Feb. 2, 2023

(54) DISPLAY DEVICE USING SEMICONDUCTOR LIGHT-EMITTING ELEMENT, AND MANUFACTURING METHOD THEREFOR

(71) Applicant: LG ELECTRONICS INC., Seoul (KR)

(72) Inventors: Hyunho LEE, Seoul (KR); Bongchu SHIM, Seoul (KR); Jaewon CHANG, Seoul (KR)

(73) Assignee: LG ELECTRONICS INC., Seoul (KR)

(21) Appl. No.: 17/791,402

(22) PCT Filed: Jan. 10, 2020
(86) PCT No.: PCT/KR2020/000467

§ 371 Date: Jul. 7, 2022

(30) Foreign Application Priority Data
Jan. 8, 2020 (KR) 10-2020-0002732

(51) Int. Cl. H01L 25/075; H01L 33/00; H01L 33/38

(52) U.S. Cl. CPC H01L 25/0753; H01L 33/38; H01L 33/0093

(57) ABSTRACT

Discussed is a display device including a plurality of semiconductor light-emitting elements; and a substrate in which the plurality of semiconductor light-emitting elements are accommodated and a wiring is disposed, wherein the plurality of semiconductor light-emitting elements each includes a sapphire layer on one side, and a plurality of electrodes on another side, the plurality of electrodes having an asymmetric shape with respect to at least one direction of the sapphire layer. Electrodes of the plurality of semiconductor light-emitting elements and the electrodes of assembly substrate are manufactured in an asymmetrical shape so that the plurality of semiconductor light-emitting elements having a size of several hundred µm can be arranged in one direction on the assembly substrate through self-assembly.

### TECHNICAL FIELD

The present disclosure relates to a display device using semiconductor light-emitting elements, and one particular implementation relates to a display device using semiconductor light-emitting elements having a size of several hundred µm or more.

### BACKGROUND ART

In recent years, in the field of display technology, liquid-crystal displays (LCDs), organic light-emitting diodes (OLED) displays, microLED displays, etc. have been competing to realize large-area displays.

However, LCDs have problems such as slow response time and low efficiency of light produced by a backlight, and OLEDs have disadvantages such as short lifetime, low mass-production yield, and low efficiency.

On the contrary, semiconductor light-emitting diodes (microLEDs) with a diameter or cross-sectional area less than 100 µm, when used in displays, may offer very high efficiency because the displays do not need a polarizer to absorb light. However, large-scale displays require several millions of semiconductor light-emitting diodes, which makes it difficult to transfer the devices compared to other technologies.

Some of the technologies currently in development for the transfer process include pick & place, laser lift-off (LLO), and self-assembly. Among these technologies, the self-assembly approach is a method that allows semiconductor light-emitting diodes to find their positions on their own in a fluid, which is most advantageous in realizing large-screen display devices.

Self-assembly methods may include a method of directly assembling a semiconductor light-emitting element on a final substrate to be used in a product, and a method of assembling a semiconductor light-emitting element on an assembly substrate and transferring the semiconductor light-emitting element to a final substrate through an additional transfer process. The direct assembly method on the final substrate is efficient in terms of process, and the method using the assembly substrate is advantageous in terms of additionally using a structure for self-assembly without limitation. Therefore, the two methods are selectively used.

Meanwhile, when manufacturing a display, a semiconductor light-emitting element (mini-LED) having a diameter or cross-sectional area of 100 µm or more may be used instead of microLED. However, the mini-LED also has a difficulty in transfer compared to another technology such as the microLED.

### DISCLOSURE OF INVENTION

### Technical Problem

The present disclosure describes a display device using semiconductor light-emitting elements having a structure in which the semiconductor light-emitting elements having a size of several hundred µm can be uniformly aligned on an assembly substrate through self-assembly.

The present disclosure also describes a method for manufacturing a display device using semiconductor light-emitting elements having a size of several hundred µm.

### Solution to Problem

A display device according to one implementation disclosed herein may include a plurality of light-emitting elements, and a substrate in which the semiconductor light-emitting elements are accommodated and a wiring is disposed. The semiconductor light-emitting elements each may include a sapphire layer on one side, and a plurality of electrodes on another side, and has an asymmetric shape with respect to at least one direction.

In one implementation, each of the semiconductor light-emitting elements may include a first conductive electrode, a first conductive semiconductor layer disposed on the sapphire layer and having the first conductive electrode thereon, an active layer formed on the first conductive semiconductor layer; a second conductive semiconductor layer formed on the active layer, and a second conductive electrode disposed on the second conductive semiconductor layer to be spaced apart from the first conductive electrode in a horizontal direction.

In one implementation, the plurality of electrodes may have different areas.

In one implementation, the plurality of electrodes may extend in a first direction and a second direction, and have different lengths in one of the first direction and the second direction.

In one implementation, a thickness from one surface of the sapphire layer on which the first conductive semiconductor layer is formed to another surface of the sapphire layer may be thicker than a thickness from the one surface of the sapphire layer on which the first conductive semiconductor layer is formed to the first conductive electrode and a thickness from the one surface of the sapphire layer on which the first conductive semiconductor layer is formed to the second conductive electrode.

In one implementation, the plurality of electrodes may have a magnetic substance.

A method for manufacturing a display device according to an implementation disclosed herein may include inserting semiconductor light-emitting elements into a chamber containing a fluid, taking an assembly substrate including assembly electrodes extending in one direction to an assembly position on an upper portion of the chamber, and seating the semiconductor light-emitting elements on preset positions of the assembly substrate using a magnetic field and an electric field. The semiconductor light-emitting elements each may include a sapphire layer on one side, and a plurality of electrodes on another side, and have an asymmetric shape with respect to at least one direction.

In one implementation, the assembly electrodes may form pair electrodes between adjacent assembly electrodes, and the semiconductor light-emitting elements may be seated such that an electrode having at least a larger area of two different electrodes overlaps the assembly electrodes forming the pair electrodes at the same time.

In one implementation, the sapphire layer may exhibit a polarization smaller than that of the fluid in a predetermined electric field frequency range.

In one implementation, the pair electrodes may include protrusions protruding from surfaces facing each other.

In one implementation, the protrusions of the assembly electrodes forming the pair electrodes may have different protrusion lengths.

In one implementation, the protrusions may include a first portion and a second portion extending in different directions, and the protrusions may alternatively protrude from the assembly electrodes forming the pair electrodes.

In one implementation, the method may further include transferring the semiconductor light-emitting elements seated on preset positions of the assembly substrate to a transfer substrate; and transferring the semiconductor light-emitting elements transferred to the transfer substrate onto a substrate on which wiring is formed.

### Advantageous Effects of Invention

According to one embodiment of the present invention, electrodes of a semiconductor light-emitting element and electrodes of an assembly substrate can be manufactured in an asymmetric shape. This can allow semiconductor light-emitting elements having a size of several hundred µm can be arranged in one direction on the assembly substrate through self-assembly.

In addition, the semiconductor light-emitting elements can be self-assembled at high speed.

### BRIEF DESCRIPTION OF DRAWINGS

FIG. 1 is a conceptual view illustrating one implementation of a display device using semiconductor light-emitting elements.

FIG. 2 is a partial enlarged view of the portion A in the display device of FIG. 1.

FIG. 3 is an enlarged view of the semiconductor light-emitting element of FIG. 2.

FIG. 4 is an enlarged view illustrating another implementation of the semiconductor light-emitting element of FIG. 2.

FIGS. 5A to 5E are conceptual diagrams illustrating a new process for manufacturing the semiconductor light-emitting element.

FIG. 6 is a conceptual diagram illustrating an example of a device for self-assembling semiconductor light-emitting elements.

FIG. 7 is a block diagram of the self-assembly device of FIG. 6.

FIGS. 8A to 8E are conceptual view illustrating a process for self-assembling semiconductor light-emitting elements using the self-assembly device of FIG. 6.

FIG. 9 is a conceptual view illustrating the semiconductor light-emitting element of FIGS. 8A to 8E.

FIGS. 10A to 10Care conceptual diagrams illustrating a state in which the semiconductor light-emitting elements are transferred after a self-assembling process according to the present disclosure.

FIGS. 11 to 13 are flowcharts illustrating a method for manufacturing a display device including semiconductor light-emitting elements that emit red (R), green (G), and blue (B) light.

FIG. 14 is a conceptual view illustrating a semiconductor light-emitting element in accordance with an implementation of the present disclosure.

FIG. 15 is a view illustrating the related art semiconductor light-emitting element (symmetric electrode type) and a semiconductor light-emitting element (asymmetric electrode type) according to an implementation of the present disclosure.

FIG. 16 is a conceptual view illustrating a state in which a semiconductor light-emitting elements are assembled on an assembly substrate in accordance with an implementation.

FIG. 17 is a conceptual view illustrating a comparison between a correctly assembled state and an incorrectly assembled state of semiconductor light-emitting elements on an assembly substrate in accordance with an implementation.

(a) of FIG. 18 is a view illustrating a part of an assembly substrate in accordance with an implementation of the present disclosure, and (b) of FIG. 18 is a view illustrating a surface on which electrodes of a semiconductor light-emitting element are disposed.

FIG. 19 is a view illustrating a shape of an assembly electrode in accordance with one implementation.

FIGS. 20 and 21 are views illustrating shapes of assembly electrodes in accordance with different implementations.

### MODE FOR THE INVENTION

Description will now be given in detail according to exemplary implementations disclosed herein, with reference to the accompanying drawings. For the sake of brief description with reference to the drawings, the same or equivalent components may be provided with the same or similar reference numbers, and description thereof will not be repeated. In general, a suffix such as "module" and "unit" may be used to refer to elements or components. Use of such a suffix herein is merely intended to facilitate description of the specification, and the suffix itself is not intended to give any special meaning or function. In describing the present disclosure, if a detailed explanation for a related known function or construction is considered to unnecessarily divert the gist of the present disclosure, such explanation has been omitted but would be understood by those skilled in the art. The accompanying drawings are used to help easily understand the technical idea of the present disclosure and it should be understood that the idea of the present disclosure is not limited by the accompanying drawings. It will be understood that when an element such as a layer, area or substrate is referred to as being "on" another element, it can be directly on the element, or one or more intervening elements may also be present.

A display device disclosed herein may include a mobile phone, a smart phone, a laptop computer, a digital broadcast terminal, a personal digital assistant (PDA), a portable multimedia player (PMP), a navigator, a slate PC, a tablet PC, an ultrabook, a digital TV, a desktop computer, and the like. However, the configuration according to the implementation described herein can be applied as long as it can include a display even of it is a new product form to be developed later.

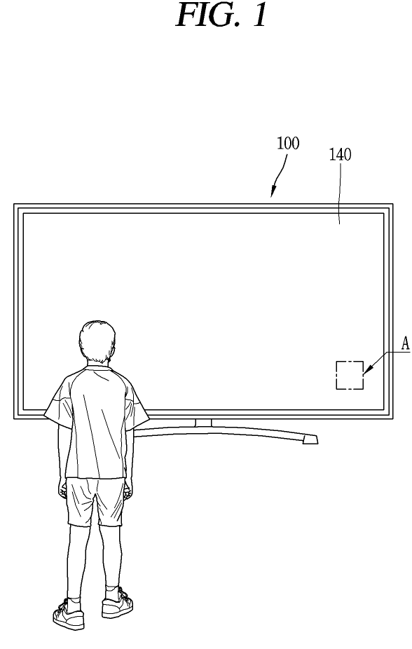

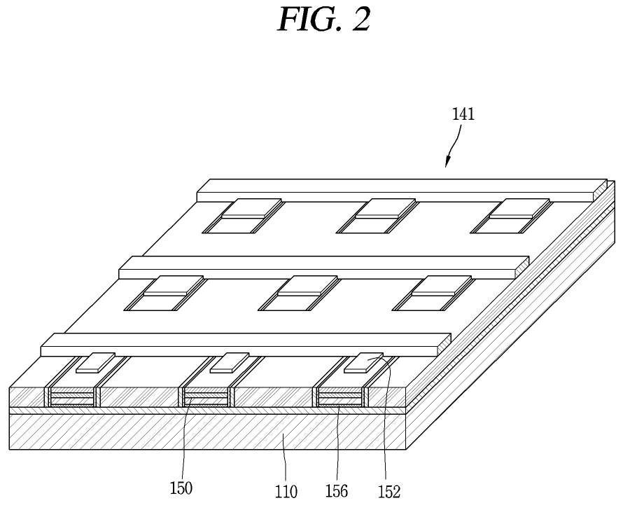

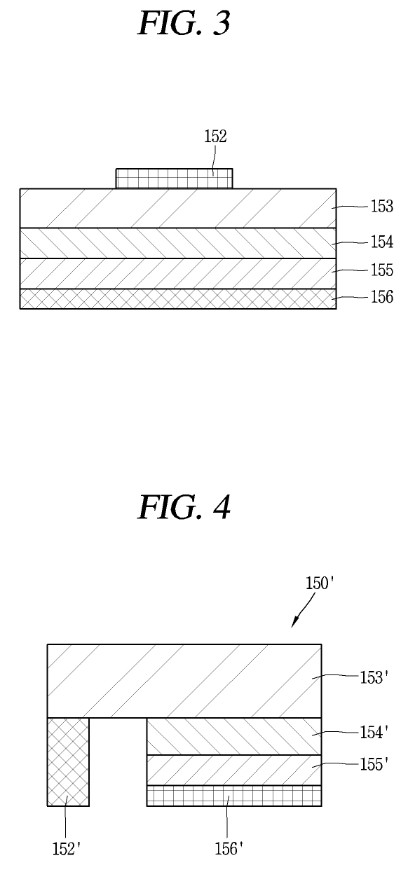

FIG. 1 is a conceptual view illustrating one implementation of a display device using semiconductor light-emitting elements, FIG. 2 is a partial enlarged view of the portion A in the display device of FIG. 1, FIG. 3 is an enlarged view of the semiconductor light-emitting element of FIG. 2, and FIG. 4 is an enlarged view illustrating another implementation of the semiconductor light-emitting element of FIG. 2.

As illustrated, information processed by a controller of a display device 100 may be output on a display module 140. A closed loop-shaped case 101 that runs around the edge of the display module 140 may define the bezel of the display device.

The display module 140 may include a panel 141 that displays an image, and the panel 141 may include micro-sized semiconductor light-emitting elements (or diodes) 150 and a wiring substrate 110 where the semiconductor light-emitting elements 150 are mounted.

The wiring substrate 110 may be provided with wirings, which can be connected to n-type electrodes 152 and p-type electrodes 156 of the semiconductor light-emitting elements 150. As such, the semiconductor light-emitting elements 150 may be provided on the wiring substrate 110 as individual pixels that emit light on their own.

The image displayed on the panel 141 may be visual information, which is rendered by controlling the light emission of unit pixels (sub-pixels) arranged in a matrix configuration independently through the wirings.

The present disclosure takes microLEDs (light-emitting diodes) as an example of the semiconductor light-emitting elements 150 which convert current into light. The microLEDs may be light-emitting elements that are small in size less than 100 micron meters. The semiconductor light-emitting elements 150 may have light-emitting regions of red, green, and blue, and unit pixels may be produced by combinations of these colors. That is, the unit pixels are the smallest units for producing one color. Each unit pixel may contain at least three microLEDs.

More specifically, referring to FIG. 3, the semiconductor light-emitting element 150 may have a vertical structure.

For example, the semiconductor light-emitting elements 150 may be implemented as high-power light-emitting elements that are composed mostly of gallium nitride (GaN), with some indium (In) and/or aluminum (Al) added to it, and emit light of various colors.

Such a vertical semiconductor light-emitting element may include a p-type electrode 156, a p-type semiconductor layer 155 disposed on the p-type semiconductor layer 156, an active layer 154 disposed on the p-type semiconductor layer 155, an n-type semiconductor layer 153 disposed on the active layer 154, and an n-type electrode 152 disposed on the n-type semiconductor layer 153. In this case, the p-type electrode 156 at the bottom may be electrically connected to a p-electrode of the wiring substrate, and the upper n-type electrode 152 at the top may be electrically connected to an n-electrode above the semiconductor light-emitting element. The electrodes can be disposed in an upward/downward direction in the vertical semiconductor light-emitting element 150, thereby providing a great advantage of reducing a chip size.

In another example, referring to FIG. 4, the semiconductor light-emitting elements may be flip chip-type light-emitting elements.

As an example of such a flip chip-type light-emitting element, the semiconductor light-emitting element 250 may include a p-type electrode 256, a p-type semiconductor layer 255 disposed on the p-type layer 256, an active layer 254 disposed on the p-type semiconductor layer 255, an n-type semiconductor layer 253 disposed on the active layer 254, and an n-type electrode 252 vertically separated from the p-type electrode 256 on the n-type semiconductor layer 253. In this case, both the p-type electrode 256 and the n-type electrode 252 may be electrically connected to a p electrode and an n electrode of the wiring substrate, below the semiconductor light-emitting element.

The vertical semiconductor light-emitting element and a horizontal light-emitting element each may be used as a green semiconductor light-emitting element, blue semiconductor light-emitting element, or red semiconductor light-emitting element. The green semiconductor light-emitting element and the blue semiconductor light-emitting element may be implemented as high-power light-emitting elements that are composed mostly of gallium nitride (GaN), with some indium (In) and/or aluminum (Al) added to it, and emit green and blue light, respectively. As an example, the semiconductor light-emitting elements may be made of gallium nitride thin films which include various layers of n-Gan, p-GaN, AlGaN, InGaN, etc. More specifically, the p-type semiconductor layer may be P-type GaN, and the n-type semiconductor layer may be N-type GaN. However, for the red semiconductor light-emitting element, the p-type semiconductor layer may be P-type GaAs, and the n-type semiconductor layer may be N-type GaAs.

Moreover, the p-type semiconductor layer may be P-type GaN doped with Mg on the p electrode, and the n-type semiconductor layer may be N-type GaN doped with Si on the n electrode. In this case, the above-described semiconductor light-emitting elements may be semiconductor light-emitting elements without the active layer.

In some examples, referring to FIGS. 1 to 4, because of the very small size of the light-emitting elements, self-emissive, high-definition unit pixels may be arranged on the display panel, and therefore the display device can deliver high picture quality.

In the display device using the semiconductor light-emitting elements, semiconductor light-emitting elements may be grown on a wafer, formed through mesa and isolation, and used as individual pixels. In this case, the micro-sized semiconductor light-emitting elements 150 should be transferred onto a wafer, at preset positions on a substrate of the display panel. One of the transfer technologies available may be pick and place, but it has a low success rate and requires a lot of time. In another example, a number of diodes may be transferred at a time by using a stamp or roll, which, however, is not suitable for large-screen displays because of limited yields. The present disclosure proposes a new method and device for manufacturing a display device that can solve these problems.

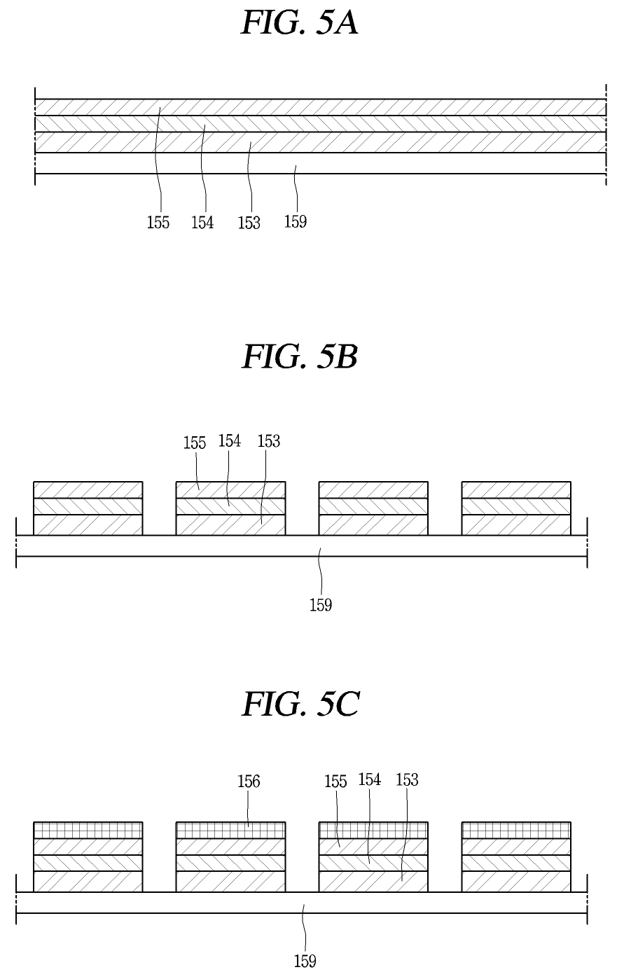

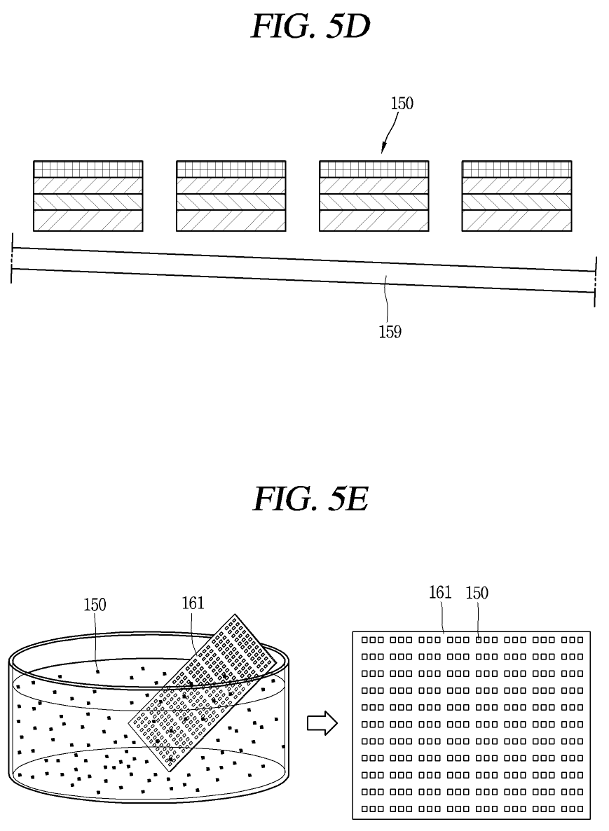

To this end, a new method for manufacturing a display device will be described first below. FIGS. 5A to 5E are conceptual views illustrating a new process for manufacturing the semiconductor light-emitting elements (or diodes).

In this specification, a display device using passive matrix (PM) type semiconductor light-emitting elements will be illustrated. However, an example described below may also be applicable to an active matrix (AM) type semiconductor light-emitting element. Also, although the illustration will be given of how horizontal semiconductor light-emitting elements are self-assembled, it may also be applied to self-assembling of vertical semiconductor light-emitting elements.

First of all, according to the manufacturing method, a first conductive semiconductor layer 153, an active layer 154, and a second conductive semiconductor layer 155 may be grown on a growth substrate 159 (FIG. 5A).

Once the first conductive semiconductor layer 153 is grown, the active layer 154 may be grown on the first conductive semiconductor layer 153 and then the second conductive semiconductor layer 155 may be grown on the active layer 154. By sequentially growing the first conductive semiconductor layer 153, the active layer 154, and the second conductive semiconductor layer 155, the first conductive semiconductor layer 153, the active layer 154, and the second conductive semiconductor layer 155 may form a stack structure as illustrated in FIG. 5A.

In this case, the first conductive semiconductor layer 153 may be a p-type semiconductor layer, and the second conductive semiconductor layer 155 may be an n-type semiconductor layer. However, the present disclosure is not necessarily limited to this, and the first conductive type may be n-type and the second conductive type may be p-type.

Moreover, although this exemplary implementation is illustrated by assuming the presence of the active layer, the active layer may be omitted if necessary, as stated above. In an example, the p-type semiconductor layer may be P-type GaN doped with Mg, and the n-type semiconductor layer may be N-type GaN doped with Si on the n electrode.

The growth substrate 159 (wafer) may be formed of, but not limited to, light-transmissive material, for example, one of sapphire (AI2O3), GaN, ZnO, and AIO. Also, the growth substrate 159 may be made of a material suitable for growing semiconductor materials, namely, a carrier wafer. The growth substrate 2101 may also be formed of a material having high thermal conductivity. The growth substrate 2101 may use at least one of a SiC substrate having higher thermal conductivity than the sapphire (AI2O3) substrate, Si, GaAs, GaP, InP and Ga2O3, in addition to a conductive substrate or an insulating substrate.

Next, a plurality of semiconductor light-emitting elements may be formed by removing at least parts of the first conductive semiconductor layer 153, the active layer 154, and the second conductive semiconductor layer 155 (FIG. 5B).

More specifically, isolation may be performed so that the plurality of light-emitting elements form a light-emitting diode array. That is, a plurality of semiconductor light-emitting elements may be formed by vertically etching the first conductive semiconductor layer 153, the active layer 154, and the second conductive semiconductor layer 155.

In the case of horizontal semiconductor light-emitting elements, a mesa process may be performed which exposes the first conductive semiconductor layer 153 to the outside by vertically removing part of the active layer 154 and the second conductive semiconductor layer 155, and then isolation may be performed which forms an array of semiconductor light-emitting elements by etching the first conductive semiconductor layer 153.

Next, a second conductive electrode 156 (or p-type electrode) may be formed on one surface of the second conductive semiconductor layer 155 (FIG. 5C). The second conductive electrode 156 may be formed by a deposition method such as sputtering, but the present disclosure is not necessarily limited to this. In a case where the first conductive semiconductor layer and the second conductive semiconductor layer are an n-type semiconductor layer and a p-type semiconductor layer, respectively, the second conductive electrode 156 may serve as an n-type electrode.

Next, the growth substrate 159 may be removed, thus leaving a plurality of semiconductor light-emitting elements. For example, the growth substrate 159 may be removed using laser lift-off (LLO) or chemical lift-off (CLO) (FIG. 5D).

Afterwards, the step of mounting the semiconductor light-emitting elements 150 on a substrate in a chamber filled with a fluid may be performed (FIG. 5E).

For example, the semiconductor light-emitting elements 150 and the substrate 161 may be put into a chamber filled with a fluid, and the semiconductor light-emitting elements may be self-assembled onto the substrate 161 using fluidity, gravity, surface tension, etc. In this case, the substrate may be an assembly substrate 161.

In another example, a wiring substrate, instead of the assembly substrate 161, may be put into a fluid chamber, and the semiconductor light-emitting elements 150 may be mounted directly onto the wiring substrate. In this case, the substrate may be a wiring substrate. For convenience of explanation, the present disclosure is illustrated with an example in which the semiconductor light-emitting diodes 150 are mounted onto the assembly substrate 161.

To facilitate the mounting of the semiconductor light-emitting elements 150 onto the assembly substrate 161, cells (not shown) into which the semiconductor light-emitting elements 150 are fitted may be provided on the assembly substrate 161. Specifically, cells where the semiconductor light-emitting elements 150 are mounted may be disposed on the assembly substrate 161 at positions where the semiconductor light-emitting elements 150 are aligned with wiring electrodes. The semiconductor light-emitting elements 150 may be assembled to the cells as they move within the fluid.

After arraying the semiconductor light-emitting elements 150 on the assembly substrate 161, the semiconductor light-emitting elements 150 may be transferred to the wiring substrate from the assembly substrate 161, thereby enabling a large-area transfer across a large area. Thus, the assembly substrate 161 may be referred to as a temporary substrate.

Meanwhile, the above-explained self-assembly method requires a higher transfer yield so that it can be applied to the manufacture of large-screen displays. The present disclosure proposes a method and device that minimizes the effects of gravity or friction and avoids non-specific binding, in order to increase the transfer yield.

In this case, in the display device according to the present disclosure, a magnetic material may be placed on the semiconductor light-emitting elements so that the semiconductor light-emitting elements are moved by magnetic force, and the semiconductor light-emitting elements may be mounted at preset positions by an electric field in the process of being moved. This transfer method and device will be described in more detail below with reference to the accompanying drawings.

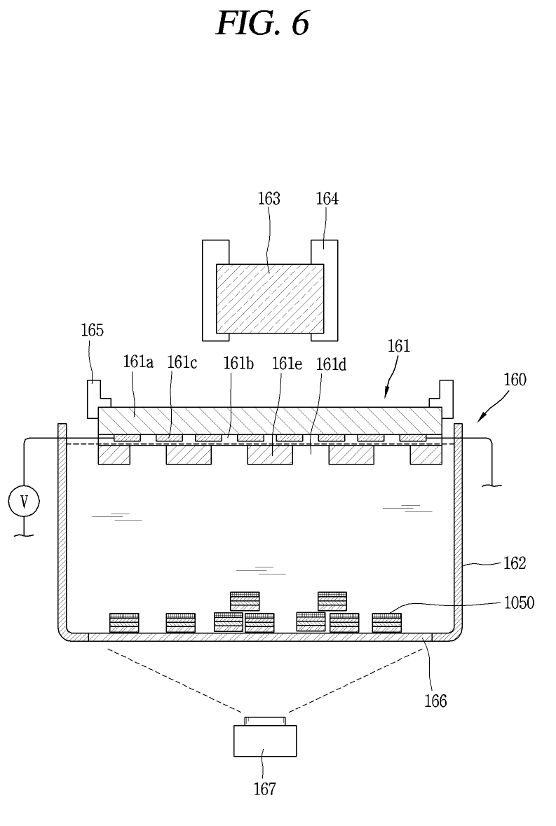

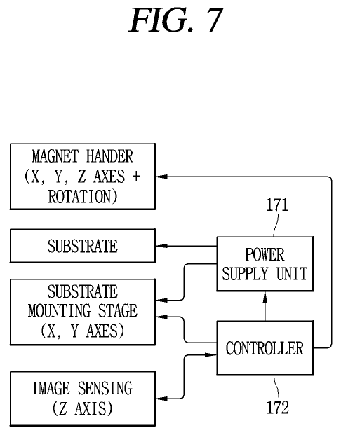

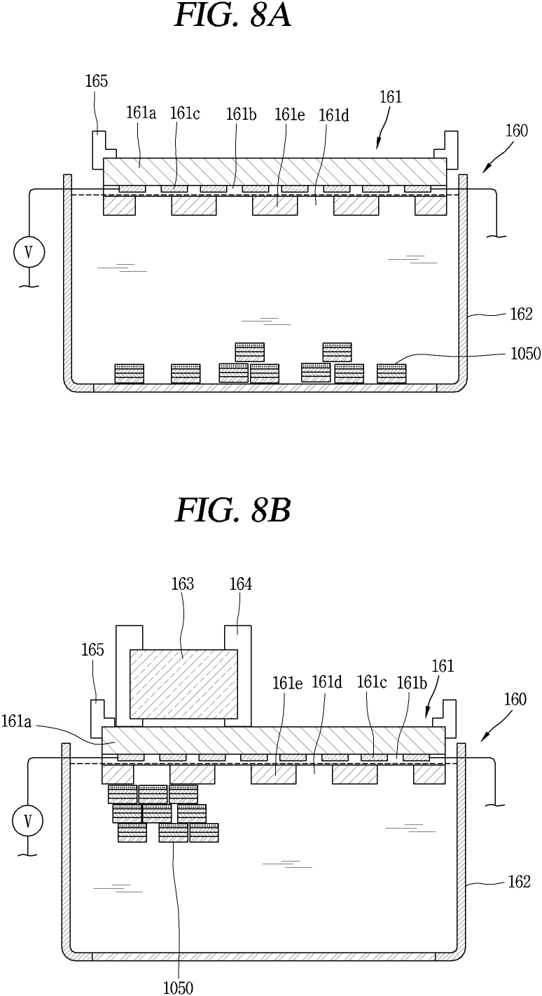

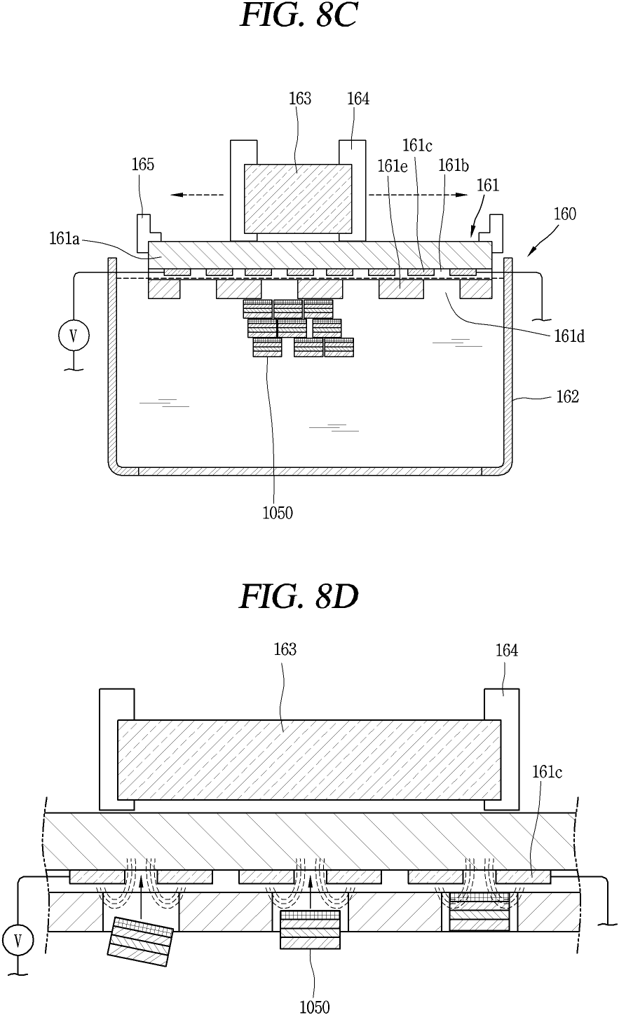

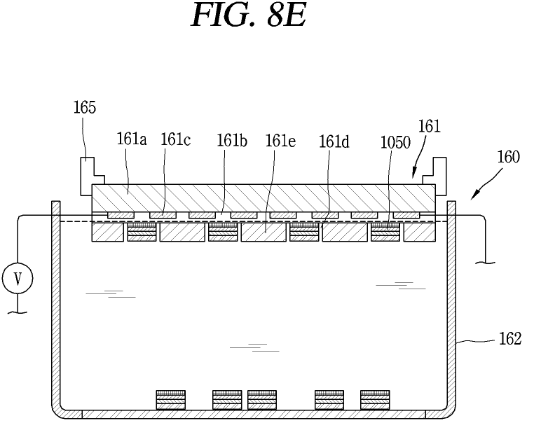

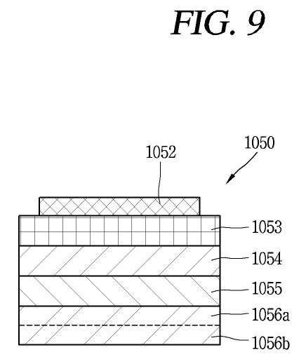

FIG. 6 is a conceptual diagram illustrating an example of a device for self-assembling semiconductor light-emitting elements and FIG. 7 is a block diagram of the self-assembly device of FIG. 6. FIGS. 8A to 8E are conceptual view illustrating a process for self-assembling semiconductor light-emitting elements using the self-assembly device of FIG. 6 and FIG. 9 is a conceptual view illustrating the semiconductor light-emitting element of FIGS. 8A to 8E.

Referring to FIGS. 6 and 7, the self-assembly device 160 may include a fluid chamber 162, a magnet 163, and a position controller 164.

The fluid chamber 162 may define a space for receiving a plurality of semiconductor light-emitting elements. The space may be filled with a fluid, and the fluid may be an assembly solution, which includes water or the like. Thus, the fluid chamber 162 may be a water tank and configured as an open-type. However, the present disclosure is not limited to this, and the fluid chamber 162 may be a closed-type chamber in which the space is in a closed state.

A substrate 161 may be placed in the fluid chamber 162 so that an assembly surface where the semiconductor light-emitting elements 150 are assembled faces downwards. For example, the substrate 161 may be fed to an assembly site by a feed unit (transfer unit), and the transfer unit may include a stage 165 where the substrate is mounted. The position of the stage 165 may be adjusted by the controller, whereby the substrate 161 can be fed to the assembly site.

In this instance, the assembly surface of the substrate 161 at the assembly site may face the bottom of the fluid chamber 162. As illustrated in the drawings, the assembly surface of the substrate 161 may be placed to be soaked with the fluid in the fluid chamber 162. Thus, the semiconductor light-emitting elements 150 in the fluid may be moved to the assembly surface.

The substrate 161 may be an assembly substrate where an electric field can be formed, and may include a base portion 161a, a dielectric layer 161b, and a plurality of electrodes 161c.

The base portion 161a may be made of an insulating material, and the plurality of electrodes 161c may be thin-film or thick-film bi-planar electrodes that are patterned on one surface of the base portion 161a. The electrodes 161c may be formed of a stack of Ti/Cu/Ti, Ag paste, ITO, etc.

The dielectric layer 161b may be made of an inorganic material such as SiO2, SiNx, SiON, A12O3, TiO2, HfO2, etc. Alternatively, the dielectric layer 161b may be an organic insulator and configured as a single layer or multi-layers. The thickness of the dielectric layer 161b may range from several tens of nm to several µm.

Further, the substrate 161 according to the present disclosure may include a plurality of cells 161d that are separated by barrier walls 161e. The cells 161d may be sequentially arranged in one direction and made of polymer material. Also, the barrier walls 161e defining the cells 161d may be shared by neighboring cells 161d. The barrier walls 161e may protrude from the base portion 161a, and the cells 161d may be sequentially arranged in one direction along the barrier walls 161e. More specifically, the cells 161d may be sequentially arranged in column and row directions and have a matrix configuration.

As illustrated in the drawings, the cells 161d may have recesses for receiving the semiconductor light-emitting elements 150, and the recesses may be spaces defined by the barrier walls 161e. The recesses may have a shape identical or similar to the shape of the semiconductor light-emitting elements. For example, if the semiconductor light-emitting elements are rectangular, the recesses may be rectangular too. Moreover, although not shown, the recesses formed in the cells may be circular if the semiconductor light-emitting diodes are circular. Further, each cell may be configured to receive one semiconductor light-emitting element. That is, one cell may receive one semiconductor light-emitting element.

Meanwhile, the plurality of electrodes 161c may have a plurality of electrode lines that are placed at the bottom of the cells 161d, and the electrode lines may extend to neighboring cells.

The plurality of electrodes 161c may be placed beneath the cells 161d, and different polarities may be applied to create an electric field within the cells 161d. To form an electric field, the dielectric layer 161b may form the bottom of the cells 161d while covering the electrodes 161c. With this structure, when different polarities are applied to a pair of electrodes 161c beneath each cell 161d, an electric field may be formed and the semiconductor light-emitting elements can be inserted into the cells 161d by the electric field.

The electrodes of the substrate 161 at the assembly site may be electrically connected to a power supply 171. The power supply 171 may perform the function of generating the electric field by applying power to the electrodes.

As shown in the drawings, the self-assembly device may have the magnet 163 for applying magnetic force to the semiconductor light-emitting elements. The magnet 163 may be disposed at a distance from the fluid chamber 162 to apply magnetic force to the semiconductor light-emitting elements 150. The magnet 163 may be disposed to face an opposite side of the assembly surface of the substrate 161, and the position of the magnet 163 may be controlled by the position controller 164 connected to the magnet 163.

The semiconductor light-emitting elements 1050 may have a magnetic material so that they can be moved within the fluid by a magnetic field.

Referring to FIG. 9, a semiconductor light-emitting element having a magnetic material may include a first conductive electrode 1052, a second conductive electrode 1056, a first conductive semiconductor layer 1053 on which the first conductive electrode 1052 is disposed, a second conductive semiconductor layer 1055 which overlaps the first conductive semiconductor layer 1052 and on which the second conductive electrode 1056 is disposed, and an active layer 1054 disposed between the first and second conductive semiconductor layers 1053 and 1055.

Here, the first conductive may refer to p-type, and the second conductive type may refer to n-type, or vice versa. As stated previously, the semiconductor light-emitting diode may be formed without the active layer.

Meanwhile, the first conductive electrode 1052 may be formed after the semiconductor light-emitting element is assembled onto the wiring substrate by the self-assembling of the semiconductor light-emitting element. Further, the second conductive electrode 1056 may include a magnetic material. The magnetic material may refer a magnetic metal. The magnetic material may be Ni, SmCo, etc. In another example, the magnetic material may include at least one of Gd-based, La-based, and Mn-based materials.

The magnetic material may be provided in the form of particles on the second conductive electrode 1056. Alternatively, one layer of a conductive electrode including a magnetic material may be made of the magnetic material. As an example, the second conductive electrode 1056 of the semiconductor light-emitting element 1050 may include a first layer 1056a and a second layer 1056b, as illustrated in FIG. 9. Here, the first layer 1056a may include a magnetic material, and the second layer 1056b may include a metal material other than the magnetic material.

As illustrated in the drawing, in this example, the first layer 1056a including the magnetic material may be disposed in contact with the second conductive semiconductor layer 1055. In this case, the first layer 1056a may be disposed between the second layer 1056b and the second conductive semiconductor layer 1055. The second layer 1056b may be a contact metal that is connected to the second electrode on the wiring substrate. However, the present disclosure is not necessarily limited to this, and the magnetic material may be disposed on one surface of the first conductive semiconductor layer.

Still referring to FIGS. 6 and 7, more specifically, on top of the fluid chamber of the self-assembly device, a magnet handler capable of automatically or manually moving the magnet 163 on the x, y, and z axes or a motor capable of rotating the magnet 163 may be provided. The magnet handler and motor may constitute the position controller 164. As such, the magnet 163 may rotate in a horizontal, clockwise, or counterclockwise direction with respect to the substrate 161.

Meanwhile, the fluid chamber 162 may be provided with a light-transmissive bottom plate 166, and the semiconductor light-emitting elements may be disposed between the bottom plate 166 and the substrate 161. An image sensor 167 may be disposed to face the bottom plate 166 so as to monitor the inside of the fluid chamber 162 through the bottom plate 166. The image sensor 167 may be controlled by a controller 172, and may include an inverted-type lens, CCD, etc. so as to observe the assembly surface of the substrate 161.

The self-assembly device may be configured to use a magnetic field and an electric field in combination. With this, the semiconductor light-emitting elements can be mounted at preset positions on the substrate by the electric field while being moved by changes in the position of the magnet. Hereinafter, the assembly process using the self-assembly device will be described in more detail.

First of all, a plurality of semiconductor light-emitting elements 1050 having a magnetic material may be formed through the process explained with reference to FIGS. 5A to 5C. In this case, the magnetic material may be deposited onto the semiconductor light-emitting elements in the process of forming the second conductive electrode of FIG. 5C.

Next, the substrate 161 may be fed to an assembly site, and the semiconductor light-emitting elements 1050 may be put into the fluid chamber 162 (FIG. 8A).

As described above, the assembly site on the substrate 161 may be a position at which the substrate 161 is placed in the fluid chamber 162 in such a way that an assembly surface where the semiconductor light-emitting elements 150 are assembled faces downwards.

In this case, some of the semiconductor light-emitting elements 1050 may sink to the bottom of the fluid chamber 162 and some of them may float in the fluid. When the fluid chamber 162 is provided with the light-transmissive bottom plate 166, some of the semiconductor light-emitting elements 1050 may sink to the bottom plate 166.

Next, magnetic force may be applied to the semiconductor light-emitting elements 1050 so that the semiconductor light-emitting elements 1050 in the fluid chamber 162 come up to the surface (FIG. 8B).

When the magnet 163 of the self-assembly device moves to the opposite side of the assembly surface of the substrate 161 from its original position, the semiconductor light-emitting elements 1050 may float in the fluid towards the substrate 161. The original position may refer to s position at which the magnet 163 is outside the fluid chamber 162. As another example, the magnet 163 may be configured as an electromagnet. In this case, an initial magnetic force may be generated by supplying electricity to the electromagnet.

Meanwhile, in this implementation, the spacing between the assembly surface of the substrate 161 and the semiconductor light-emitting elements 1050 may be controlled by adjusting strength of the magnetic force. For example, the spacing may be controlled by using weight, buoyancy, and magnetic force of the semiconductor light-emitting elements 1050. The spacing may be several millimeters to several tens of micrometers from the outermost part of the substrate 161.

Next, magnetic force may be applied to the semiconductor light-emitting elements 1050 so that the semiconductor light-emitting elements 1050 can move in one direction within the fluid chamber 162. For example, the magnet 163 may move in a horizontal direction to the substrate, a clockwise direction, or a counterclockwise direction (FIG. 8C). In this case, the semiconductor light-emitting elements 1050 may be moved horizontally with respect to the substrate 161 by the magnetic force, with being spaced apart from the substrate 161.

Next, the semiconductor light-emitting elements 1050 may be guided to preset positions on the substrate 161 by applying an electric field so that the semiconductor light-emitting elements 1050 are mounted at the preset positions during their movement (FIG. 8C). For example, the semiconductor light-emitting elements 1050 may be moved vertically with respect to the substrate 161 by the electric field while being moved horizontally with respect to the substrate 161, thereby being placed at the preset positions of the substrate 161.

More specifically, an electric field may be generated by supplying power to bi-planar electrodes on the substrate 161, and the semiconductor light-emitting electrodes 1050 may be guided to be assembled only at the preset positions by the electric field. That is, the semiconductor light-emitting elements 1050 may be self-assembled at the assembly site on the substrate 161 by a selectively generated electric field. To this end, the substrate 161 may be provided with cells into which the semiconductor light-emitting elements 1050 are fitted.

Afterwards, unloading of the substrate 161 may be performed, thereby completing the assembly process. In a case where the substrate 161 is an assembly substrate, the assembled semiconductor light-emitting elements may be transferred onto a wiring substrate to carry out a subsequent process for realizing the display device, as described previously.

Meanwhile, after the semiconductor light-emitting elements 1050 are guided to the preset positions, the magnet 163 may be moved away from the substrate 161 such that the semiconductor light-emitting elements 1050 remaining in the fluid chamber 162 fall to the bottom of the fluid chamber 162 (FIG. 8D). In another example, when power supply is stopped in a case where the magnet 163 is an electromagnet, the semiconductor light-emitting elements 1050 remaining in the fluid chamber 162 may fall to the bottom of the fluid chamber 162.

Thereafter, the semiconductor light-emitting elements 1050 on the bottom of the fluid chamber 162 may be collected, and the collected semiconductor light-emitting elements 1050 may be re-used.

In the above-explained self-assembly device and method, parts at far distances may be concentrated near a preset assembly site by using a magnetic field in order to increase assembly yields in a fluidic assembly, and guided to be selectively assembled only at the assembly site by applying an electric field to the assembly site. In this case, the assembly substrate may be positioned on top of a water tank, with its assembly surface facing downward, thereby minimizing the effect of gravity from the weights of the parts and avoiding non-specific binding and eliminating defects. That is, the assembly substrate may be placed on the top to increase transfer yields, thus minimizing the effect of gravity or friction and avoiding non-specific binding.

As seen from above, with the configuration, a large number of semiconductor light-emitting elements can be assembled at a time in a display device where individual pixels are made up of semiconductor light-emitting elements.

As such, a large number of semiconductor light-emitting elements can be pixelated on a small-sized wafer and then transferred onto a large-area substrate. This enables the manufacture of a large-area display device at a low cost.

Meanwhile, the present disclosure provides a structure and method of an assembly substrate for increasing the yields of the self-assembly process and the process yields after the self-assembly. The present disclosure is limited to a case where the substrate 161 is used as an assembly substrate. That is, the assemble substrate to be described later is not used as the wiring substrate of the display device. Hereinafter, the substrate 161 is referred to as an assembly substrate 161.

The present disclosure improves the process yields in two respects. First, the present disclosure prevents semiconductor light-emitting elements from being mounted on undesired positions due to an electric field strongly formed at the undesired positions. Second, the present disclosure prevents the semiconductor light-emitting elements from remaining on the assemble substrate when transferring the semiconductor light-emitting elements mounted on the assemble substrate to another substrate.

The above-mentioned objectives are not individually achieved by different components. The above-described two objectives can be achieved by organic coupling of components to be described later and the assembly substrate 161 described above.

Before describing the present disclosure in detail, a post-process for manufacturing a display device after self-assembling will be described.

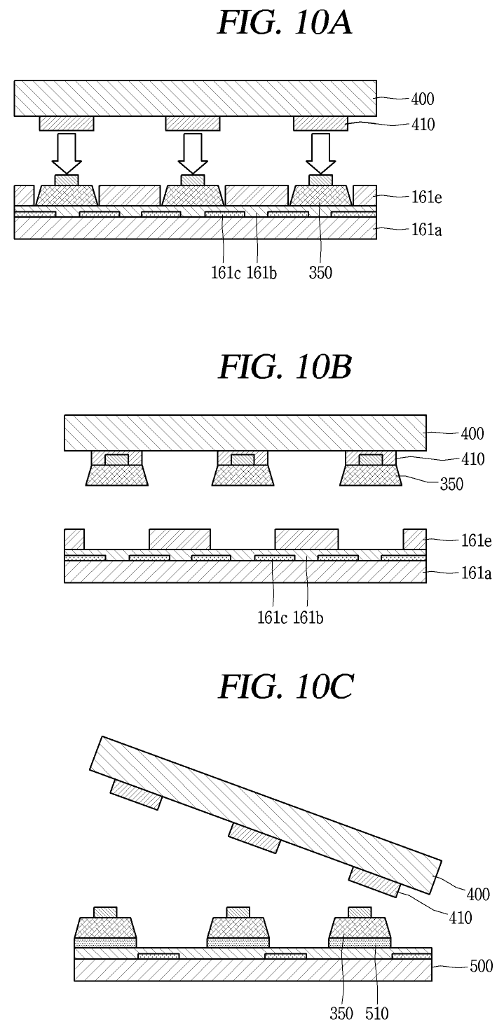

FIGS. 10A to 10C are conceptual diagrams illustrating a state in which the semiconductor light-emitting elements are transferred after a self-assembling process according to the present disclosure.

When the self-assembly process described with reference to FIGS. 8A to 8E is completed, the semiconductor light-emitting diodes are mounted on the assembly substrate 161 at preset positions. The semiconductor light-emitting diodes mounted on the assembly substrate 161 are transferred at least once to another substrate. This specification illustrates one implementation in which the semiconductor light-emitting elements mounted on the assembly substrate 161 are transferred twice, but the present disclosure is not limited thereto. The semiconductor light-emitting elements mounted on the assembly substrate 161 may be transferred to another substrate once or three times or more.

On the other hand, immediately after the self-assembly process is completed, the assembly surface of the assembly substrate 161 faces downwards (or the gravity direction). For the process after the self-assembly, the assembly substrate 161 may be turned by 180 degrees with the semiconductor light-emitting diodes mounted thereon. In this process, there is a risk that the semiconductor light-emitting diodes are likely to be separated from the assembly substrate 161. Therefore, a voltage must be applied to the plurality of electrodes 161c (hereinafter, referred to as assembly electrodes) while the assembly substrate 161 is turned. An electric field formed between the assembly electrodes prevents the semiconductor light-emitting diodes from being separated from the assembly substrate 161 while the assembly substrate 161 is turned.

When the assembly substrate 161 is turned by 180 degrees after the self-assembly process, a shape as shown in FIG. 10A is made. Specifically, as shown in FIG. 10A, the assembly surface of the assembly substrate 161 is in a state of facing upwards (or the opposite direction to gravity). In this state, a transfer substrate 400 is aligned above the assembly substrate 161.

The transfer substrate 400 is a substrate for separating the semiconductor light-emitting diodes placed on the assembly substrate 161 and transferring them to the wiring substrate. The transfer substrate 400 may be formed of PDMS (polydimethylsiloxane). Accordingly, the transfer substrate 400 may be referred to as a PDMS substrate.

The transfer substrate 400 is aligned above the assembly substrate 161 and then pressed onto the assembly substrate 161. When the transfer substrate 400 is fed above the assembly substrate 161, the semiconductor light-emitting diodes 350 mounted on the assembly substrate 161 are transferred to the transfer substrate 400 by the adhesive force of the transfer substrate 400.

To this end, surface energy between the semiconductor light-emitting diodes 350 and the transfer substrate 400 should be higher than surface energy between the semiconductor light-emitting diodes 350 and the dielectric layer 161b. When there is a greater difference between the surface energy between the semiconductor light-emitting diodes 350 and the transfer substrate 400 and the surface energy between the semiconductor light-emitting diodes 350 and the dielectric layer 161b, the probability that the semiconductor light-emitting diodes 350 are separated from the assembly substrate 161 is more increased. Therefore, it is preferable that the difference between the two surface energies is great.

Meanwhile, the transfer substrate 40 may include a plurality of protrusions 410 that allow pressure applied by the transfer substrate 400 to be concentrated on the semiconductor light-emitting diodes 350 when pressing the transfer substrate 400 onto the assembly substrate 161. The protrusions 410 may be formed at the same interval as the semiconductor light-emitting diodes mounted on the assembly substrate 161. When the transfer substrate 400 is pressed onto the assembly substrate 161 after the protrusions 410 are aligned to overlap the semiconductor light-emitting diodes 350, the pressure applied by the transfer substrate 400 can be concentrated only on the semiconductor light-emitting diodes 350. Thus, the present disclosure increases the probability that the semiconductor light-emitting elements are separated from the assembly substrate 161.

Meanwhile, in a state where the semiconductor light-emitting elements are mounted on the assembly substrate 161, parts of the semiconductor light-emitting elements are preferably exposed to the outside of recesses. If the semiconductor light-emitting elements 350 are not exposed to the outside of the recesses, the pressure applied by the transfer substrate 400 is not concentrated on the semiconductor light-emitting elements 350, which may lower the probability that the semiconductor light-emitting elements 350 are separated from the assembly substrate 161.

Lastly, referring to FIG. 10C, the step of pressing the transfer substrate 400 onto the wiring substrate 500 and transferring the semiconductor light-emitting elements 350 from the transfer substrate 400 to the wiring substrate 500 is carried out. At this time, the wiring substrate 500 may be provided with protrusions 510. The transfer substrate 400 and the wiring substrate 500 are aligned so that the semiconductor light-emitting elements 350 disposed on the transfer substrate 400 overlap the protrusions 510. Thereafter, when the transfer substrate 400 is pressed onto the wiring substrate 500, the probability that the semiconductor light-emitting elements 350 are separated from the transfer substrate 400 may increase due to the protrusions 510.

On the other hand, in order for the semiconductor light-emitting elements 350 disposed on the transfer substrate 400 to be transferred to the wiring substrate 500, surface energy between the semiconductor light-emitting elements 350 and the wiring substrate 500 should be higher than surface energy between the semiconductor light-emitting elements 350 and the transfer substrate 400. When there is a greater difference between the surface energy between the semiconductor light-emitting elements 350 and the wiring substrate 500 and the surface energy between the semiconductor light-emitting elements 350 and the transfer substrate 400, the probability that the semiconductor light-emitting elements 350 are separated from the transfer substrate 400 is more increased. Therefore, it is preferable that the difference between the two surface energies is great.

After all the semiconductor light-emitting elements 350 disposed on the transfer substrate 400 are transferred onto the wiring substrate 500, the step of establishing electrical connection between the semiconductor light-emitting elements 350 and wiring electrodes provided on the wiring substrate may be performed. The structure of the wiring electrodes and the method of establishing the electrical connection may vary depending on the type of the semiconductor light-emitting elements 350.

Although not shown, an anisotropic conductive film may be disposed on the wiring substrate 500. In this case, the electrical connection can be established between the semiconductor light-emitting elements 350 and the wiring electrodes disposed on the wiring substrate 500, simply by pressing the transfer substrate 400 onto the wiring substrate 500.

On the other hand, when manufacturing a display device including semiconductor light-emitting elements emitting light of different colors, the method described in FIGS. 10A to 10C can be implemented in various ways. Hereinafter, a method for manufacturing a display device including semiconductor light-emitting elements that emit red (R), green (G), and blue (B) light will be described.

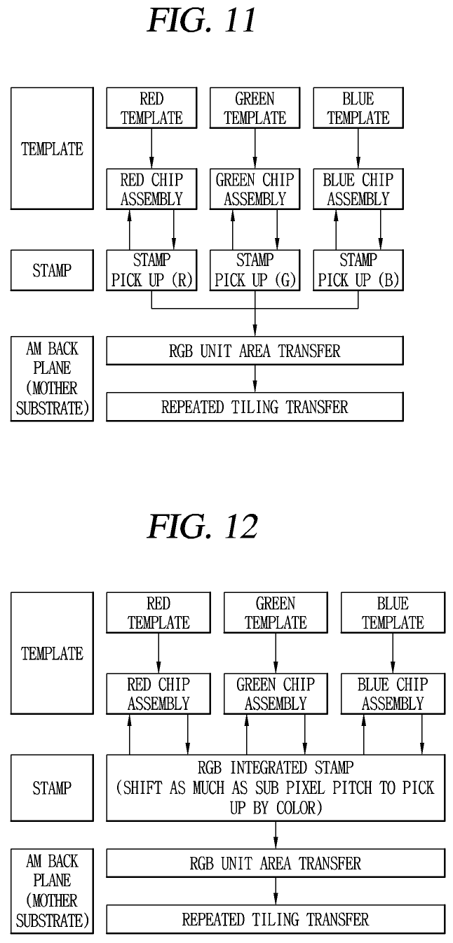

FIGS. 11 to 13 are flowcharts illustrating a method for manufacturing a display device including semiconductor light-emitting elements that emit red (R), green (G), and blue (B) light. Semiconductor light-emitting elements emitting light of different colors may be individually assembled to different assembly substrates. Specifically, the assembly substrate 161 may include a first assembly substrate on which semiconductor light-emitting elements emitting light of a first color are mounted, a second assembly substrate on which semiconductor light-emitting elements emitting light of a second color different from the first color are mounted, and a third assembly substrate on which semiconductor light-emitting elements emitting light of a third color different from the first color and the second color are mounted. Different kinds of semiconductor light-emitting elements are assembled to assembly substrates, respectively, according to the method described in FIGS. 8A to 8E. For example, semiconductor light-emitting elements emitting red (R), green (G), and blue (B) light may be assembled to the first to third assemble substrates, respectively.

Referring to FIG. 11, a RED chip, a GREEN chip, and a BLUE chip may be assembled respectively to first to third assembly substrates RED TEMPLATE, GREEN TEMPLATE, and BLUE TEMPLATE. In this state, the RED chip, GREEN chip and BLUE chip may be transferred to the wiring substrate by different transfer substrates, respectively.

Specifically, the step of transferring the semiconductor light-emitting elements, which are mounted on the assembly substrate, to the wiring substrate may include pressing a first transfer substrate (stamp R) onto the first assembly substrate RED TEMPLATE to transfer the semiconductor light-emitting elements (RED chip) emitting the light of first color from the first assembly substrate RED TEMPLATE to the first transfer substrate (stamp R), pressing a second transfer substrate (stamp G) onto the second assembly substrate GREEN TEMPLATE to transfer semiconductor light-emitting elements (GREEN chip) emitting the light of second color from the second assembly substrate GREEN TEMPLATE to the second transfer substrate (stamp G), and pressing a third transfer substrate (stamp B) onto the third assembly substrate BLUE TEMPLATE to transfer semiconductor light-emitting elements (BLUE chip) emitting the light of third color from the third assembly substrate BLUE TEMPLATE to the third transfer substrate (stamp B).

Thereafter, the step of pressing the respective first to third transfer substrates onto the wiring substrate to transfer the semiconductor light-emitting elements emitting the light of first to third colors from the first to third transfer substrates to the wiring substrate, respectively.

According to the manufacturing method according to FIG. 11, three types of assembly substrates and three types of transfer substrates are required to manufacture a display device including a RED chip, a GREEN chip, and a BLUE chip.

On the contrary, referring to FIG. 12, the RED chip, the GREEN chip, and the BLUE chip may be assembled to the first to third assembly substrates RED TEMPLATE, GREEN TEMPLATE, and BLUE TEMPLATE, respectively. In this state, the RED chip, GREEN chip and BLUE chip may be transferred to the wiring substrate by the same transfer substrate.

Specifically, the step of transferring the semiconductor light-emitting elements, which are mounted on the assembly substrate, to the wiring substrate may include pressing a transfer substrate (RGB integrated stamp) onto the first assembly substrate RED TEMPLATE to transfer the semiconductor light-emitting elements (RED chip) emitting the light of first color from the first assembly substrate RED TEMPLATE to the transfer substrate (RGB integrated stamp), pressing the transfer substrate (RGB integrated stamp) onto the second assembly substrate GREEN TEMPLATE to transfer semiconductor light-emitting elements (GREEN chip) emitting the light of second color from the second assembly substrate GREEN TEMPLATE to the transfer substrate (RGB integrated stamp), and pressing the transfer substrate (RGB integrated stamp) onto the third assembly substrate BLUE TEMPLATE to transfer semiconductor light-emitting elements (BLUE chip) emitting the light of third color from the third assembly substrate BLUE TEMPLATE to the transfer substrate (RGB integrated stamp).

In this case, the alignment positions between each of the first to third assembly substrates and the transfer substrate may be different from each other. For example, when the alignment between the assembly substrates and the transfer substrate is completed, the relative position of the transfer substrate with respect to the first assembly substrate and the relative position of the transfer substrate with respect to the second assembly substrate may be different from each other. The transfer substrate may be shifted in its alignment position by a pitch of a sub pixel every time the type of the assembly substrate is changed. In this way, when the transfer substrate is sequentially pressed onto the first to third assembly substrates, all the three kinds of chips can be transferred to the transfer substrate.

Afterwards, similar to FIG. 11, the step of pressing the transfer substrate onto the wiring substrate to transfer the semiconductor light-emitting elements emitting the light of first to third colors from the transfer substrate to the wiring substrate is performed.

According to the manufacturing method illustrated in FIG. 12, three types of assembly substrates and one type of transfer substrate are required to manufacture a display device including an RED chip, a GREEN chip, and a BLUE chip.

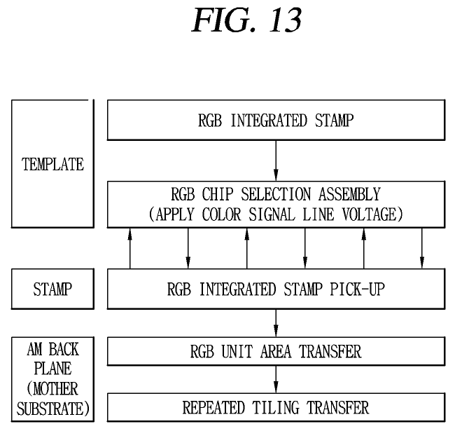

Unlike FIGS. 11 and 12, according to FIG. 13, a RED chip, a GREEN chip, and a BLUE chip may be assembled onto one assembly substrate (RGB integrated TEMPLATE). In this state, each of the RED chip, GREEN chip and BLUE chip can be transferred to the wiring substrate by the same transfer substrate (RGB integrated stamp).

According to the manufacturing method illustrated in FIG. 13, one type of assembly substrate and one type of transfer substrate are required to manufacture a display device including an RED chip, a GREEN chip, and a BLUE chip.

As described above, when manufacturing a display device including semiconductor light-emitting elements emitting light of different colors, the manufacturing method may be implemented in various ways.

Hereinafter, a display device using semiconductor light-emitting elements having a novel structure according to an implementation will be described with reference to the accompanying drawings.

The present disclosure describes a display device using semiconductor light-emitting elements having a size of several hundred µm, which can be uniformly aligned on an assembly substrate through self-assembling.

According to an implementation of the present disclosure, the display device may include semiconductor light-emitting elements 2000 according to the implementation of the present disclosure and a substrate on which the semiconductor light-emitting elements 2000 are accommodated and a wiring is formed.

The semiconductor light-emitting element 2000 according to the implementation of the present disclosure may have a length, width, and height of one hundred to several hundred µm, and may include a sapphire layer 2010 on one side and a plurality of electrodes 2030 and 2040 on another side. In addition, the semiconductor light-emitting element may have an asymmetric shape with respect to at least one direction.

The semiconductor light-emitting element 2000 according to the implementation of the present disclosure will be described in detail with reference to the accompanying drawings.

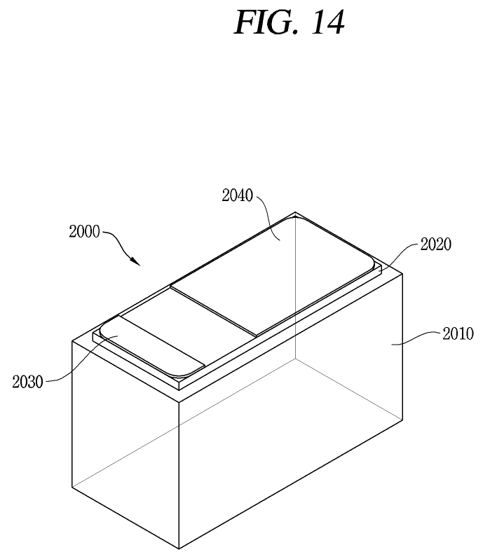

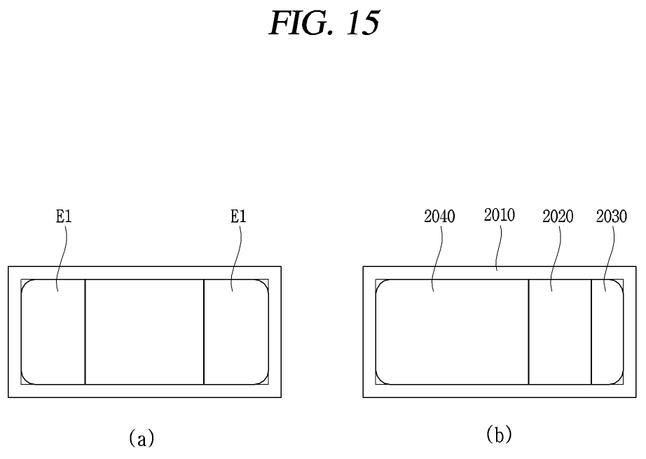

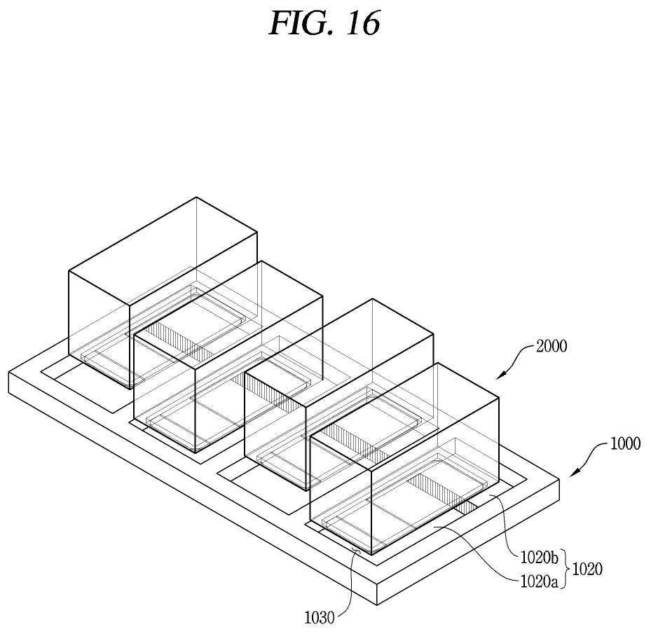

FIG. 14 is a conceptual view illustrating a semiconductor light-emitting element in accordance with an implementation of the present disclosure and FIG. 15 is a view illustrating the related art semiconductor light-emitting element (symmetric electrode type) and a semiconductor light-emitting element (asymmetric electrode type) according to an implementation of the present disclosure.

Referring to FIG. 14, the semiconductor light-emitting element 2000 according to the implementation may include a sapphire layer 2010, a first conductive semiconductor layer 2020 disposed on the sapphire layer 2010 and having a first conductive electrode 2030, an active layer (not illustrated) disposed on the first conductive semiconductor layer 2020, a second conductive semiconductor layer (not illustrated) disposed on the active layer, and a second conductive electrode 2040 disposed on the second conductive semiconductor layer to be spaced apart from the first conductive electrode 2030 in a horizontal direction.

That is, the semiconductor light-emitting element 2000 according to the implementation may be a flip-chip type element including the sapphire layer 2010.

The sapphire layer 2010 may be a portion of a growth substrate on which the first and second conductive semiconductor layers and the active layer grow during a manufacturing process of the semiconductor light-emitting element 2000, and may be included by dicing the grown semiconductor light-emitting element without separating it from the growth substrate. In this case, since a separate laser or the like is not used, a manufacturing cost can be reduced.

In the semiconductor light-emitting element 2000 according to the implementation, the first conductive semiconductor layer 2020 and the first conductive electrode 2030 may be a p-type semiconductor layer and a p-type electrode, respectively, and the second conductive semiconductor layer and the second conductive electrode 2040 may be an n-type semiconductor layer and an n-type electrode, respectively. However, the present disclosure may not be necessarily limited thereto, and the reverse may also be applicable.

In addition, according to the implementation, most of the total volume of the semiconductor light-emitting element 2000 may be occupied by the sapphire layer 2010.

Specifically, a thickness from one surface of the sapphire layer 2010 on which the first conductive semiconductor layer 2020 is disposed to another surface of the sapphire layer 2010 (or a height of the sapphire layer 2010) may be thicker than a thickness from the one surface of the sapphire layer 2010 on which the first conductive semiconductor layer 2020 is disposed to the first conductive electrode 2030 and a thickness from the one surface of the sapphire layer 2010 on which the first conductive semiconductor layer 2020 is disposed to the second conductive electrode 2040 (or heights from the first conductive semiconductor layer 2020 to the first conductive electrode 2030 and the second conductive electrode 2040).

For example, the thickness of the sapphire layer 2010 may be about 100 µm, and the respective thicknesses from the first conductive semiconductor layer 2020 to the first conductive electrode 2030 and the second conductive electrode 2040 may be 10 µm or less.

Meanwhile, the semiconductor light-emitting element 2000 according to the implementation may have an asymmetric shape with respective to at least one direction.

As illustrated in (a) of FIG. 15, the related art semiconductor light-emitting element having a size of several hundred µm is configured such that a plurality of electrodes E1 have the same area (symmetric electrode type), whereas the semiconductor light-emitting element 2000 according to the implementation, as illustrated in (b) of FIG. 15, may be configured such that the plurality of electrodes 2030 and 2040 have different areas (asymmetric electrode type).

In an implementation, the plurality of electrodes 2030 and 2040 may extend in a first direction and a second direction (a rectangular shape), and may be formed to have different lengths in any one of the first direction and the second direction so as to have different areas.

Here, the first direction may be a lengthwise direction of the first conductive semiconductor layer 2020, and the second direction may be a widthwise direction of the first conductive semiconductor layer 2020. As illustrated in FIG. 15, the first conductive electrode 30 and the second conductive electrode 2040 may have different lengths in the first direction, which is the lengthwise direction of the first conductive semiconductor layer 2020, so as to have different areas.

Also, according to the implementation, the second conductive electrode 2040 may have a larger area than the first conductive electrode 2030.

With this asymmetric structure, the semiconductor light-emitting element 2000 may be aligned in a predetermined direction during self-assembling, which will be described later.

In addition, the semiconductor light-emitting element 2000 according to the implementation may be manufactured so that the plurality of electrodes 2030 and 2040 include a magnetic material, for example, nickel (Ni) for self-assembly.

Hereinafter, a method for manufacturing a display device using the semiconductor light-emitting elements 2000 according to the aforementioned implementation will be described.

According to an implementation, the display device using the semiconductor light-emitting elements 2000 may be manufactured by a self-assembly method using an electric field and a magnetic field.

A self-assembly method according to an implementation may include inserting the semiconductor light-emitting elements 2000 into a chamber containing a fluid (S100), transferring the assembly substrate 1000 including the assembly electrodes 1020 extending in one direction to assembly positions on an upper portion of the chamber (S200), and placing the semiconductor light-emitting elements 2000 on preset positions of the assembly substrate 1000 using a magnetic field and an electric field (S300). These steps may be sequentially carried out.

The self-assembly method according to the implementation may be performed in the same manner as self-assembly of semiconductor light-emitting elements having a size of several to several tens of µm, and may also be performed in a direction opposite to gravity.

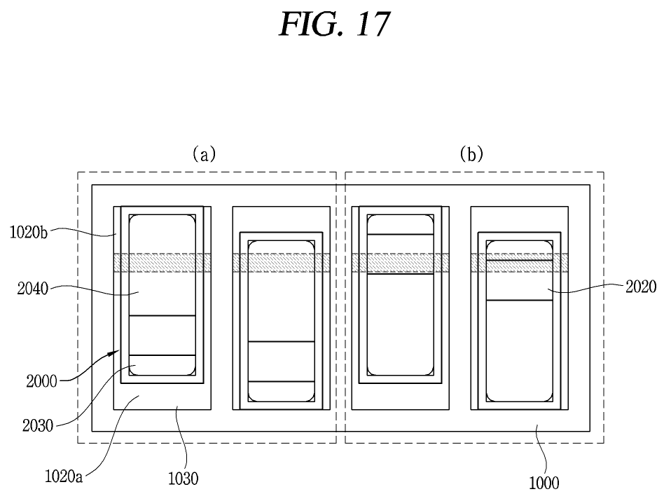

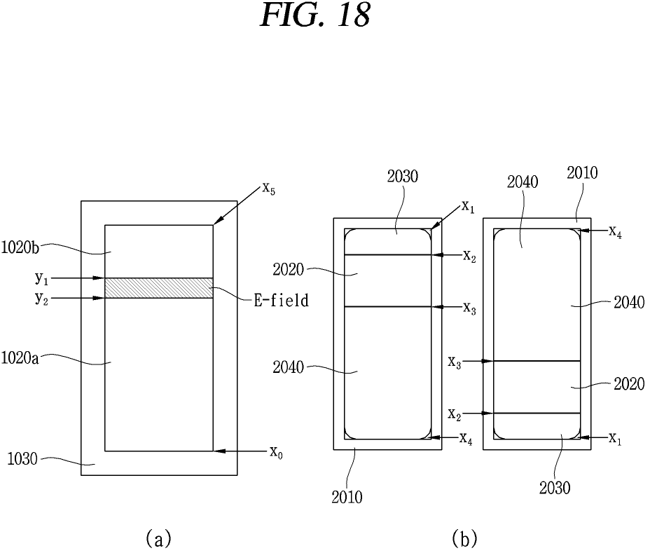

FIG. 16 is a conceptual view illustrating a state in which semiconductor light-emitting elements are assembled on an assembly substrate in accordance with an implementation, and FIG. 17 is a conceptual view illustrating a comparison between a correctly assembled state and an incorrectly assembled state of semiconductor light-emitting elements on an assembly substrate in accordance with an implementation.

Referring to FIG. 16, the assembly substrate 1000 may include an assembly electrode 1020 disposed on a base portion 1010, and receiving grooves 1030 in which the semiconductor light-emitting elements 2000 are seated. The assembly electrode 1020 may include pair electrodes 1020a and 1020b disposed between adjacent assembly electrodes, and an electric field E-field may be generated between the pair electrodes 1020a and 1020b.

The receiving groove 1030 may overlap the pair electrodes 1020a and 1020b at the same time, and in detail, may overlap protrusions 1021 a and 1021 b of the pair electrodes 1020a and 1020b. Also, the pair electrodes 1020a and 1020b may have an asymmetric shape. A description related to this will be given later.

The semiconductor light-emitting element 2000 may be seated such that a surface on which the plurality of electrodes 2030 and 2040 are formed faces the assembly electrode 1020 through self-assembling. Although not illustrated in the drawings, the assembly substrate 1000 may include a dielectric layer disposed to cover the assembly electrode 1020, and the semiconductor light-emitting element 2000 may be placed on the dielectric layer through the self-assembling such that the surface on which the plurality of electrodes 2030 and 2040 are disposed faces the assembly electrode 1020.

This direction selectivity may result from a CM (Clausius-Mossotti) factor. In detail, in an electric field frequency range formed for self-assembly, a real number part of a CM factor of sapphire has a negative (-) value, and also has smaller polarization than the fluid contained in the chamber.

Accordingly, the sapphire layer 2010 may be disposed in a direction away from the electric field, and the semiconductor light-emitting element 2000 may be aligned on the assembly substrate 1000 such that the plurality of electrodes 2030 and 2040 disposed on another side of the sapphire layer 2010 face the assembly electrode 1020.

In this case, the semiconductor light-emitting element 2000 may be placed such that an electrode having at least a larger area of the plurality of electrodes 2030 and 2040, namely, the second conductive electrode 2040 in the implementation disclosed herein overlaps an electric field formation region between the pair electrodes 1020a and 1020b.

That is, in FIG. 17, a region (a) in which the second conductive electrode 2040 overlaps the electric field formation region may indicate a state in which the semiconductor light-emitting element 2000 is correctly (normally) assembled on the assembly substrate 1000, and a region (b) in which the first conductive electrode 2030 overlaps the electric field formation region may indicate a state in which the semiconductor light-emitting element 2000 is incorrectly (erroneously) assembled on the assembly substrate 1000.

(a) of FIG. 18 is a view illustrating a part of an assembly substrate in accordance with an implementation of the present disclosure, and (b) of FIG. 18 is a view illustrating a surface on which electrodes of a semiconductor light-emitting element are disposed.

Referring to FIG. 18, a length (x0 to x5) of the receiving groove 1030 in which the semiconductor light-emitting element 2000 is seated may be longer than a length (x1 to x4) of the semiconductor light-emitting element 2000, and also longer than a length of the sapphire layer 2010.

In addition, in the state in which the semiconductor light-emitting element 2000 is erroneously assembled in the receiving groove 1030 as in the region (b) of FIG. 17, a region (y1 to y2) in which an electric field is formed between the assembly electrodes 1020 may overlap a region (x2 to x3) of the first conductive semiconductor layer 2020 exposed between the second conductive electrodes 2030 and 2040.

In other words, the semiconductor light-emitting element 2000 may be assembled on the assembly substrate 1000 so that an electric field formed between the assembly electrodes 1020 is exerted on the electrodes 2030 and 2040 of the semiconductor light-emitting element 2000, and in particular, may be selectively assembled such that the electric field can be exerted on the electrode 2040 having the wider area.

Meanwhile, the semiconductor light-emitting element 2000 may be seated such that all of the plurality of electrodes 2030 and 2040 can overlap the electric field formation region according to the shape of the assembly electrode 1020.

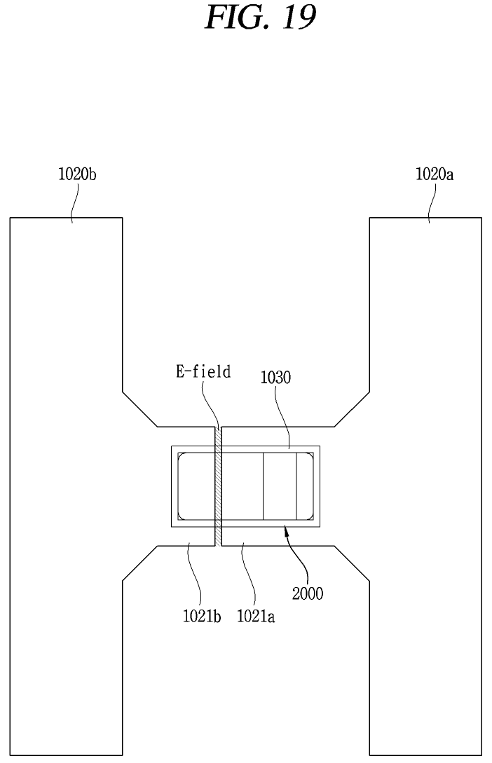

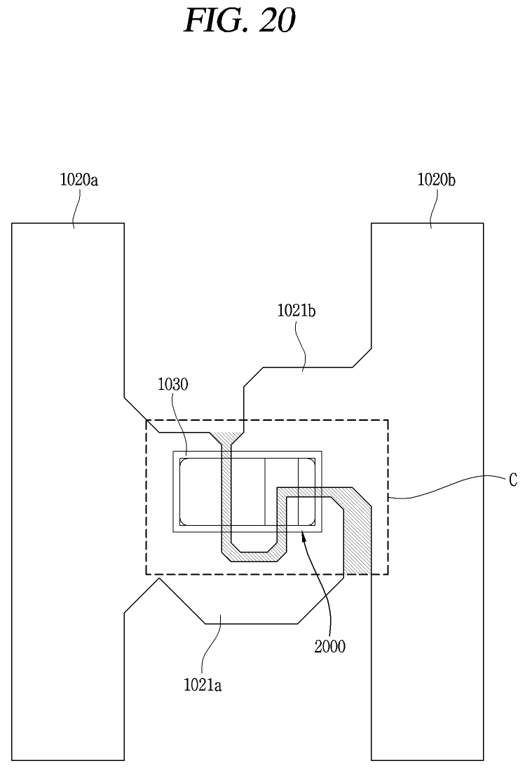

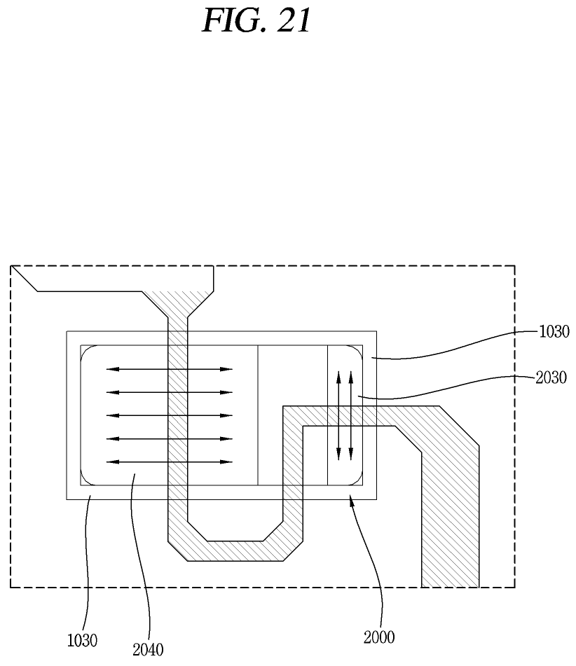

FIG. 19 is a view illustrating a shape of an assembly electrode in accordance with one implementation and FIGS. 20 and 21 are views illustrating shapes of assembly electrodes in accordance with different implementations.

The assembly electrode 1020 may include a protrusion 1021, and the pair electrodes 1020a and 1020b may include protrusions 1021a and 1021b protruding from surfaces facing each other. In addition, the protrusions 1021a and 1021b may overlap the receiving groove 1030.

According to the implementation, the protrusions 1021a and 1021 b of the pair electrodes 1020a and 1021b may be formed in an asymmetric shape. For example, the protrusions 1021a and 1021b of the pair electrodes 1020a and 1020b may have different protrusion lengths to have an asymmetric shape.

In an implementation, the protrusions 1021a and 1021 b may extend in a first direction intersecting with an extending direction of the assembly electrode 1020 as illustrated in FIG. 19, and may protrude toward each other at the same position in the extending direction of the pair electrodes 1020a and 1020b.

In this case, an electric field in a horizontal direction on the drawing may be formed between the protrusions 1021a and 1021 b of the pair electrodes 1020a and 1020b, and the semiconductor light-emitting element 2000 may be seated such that the second conductive electrode 2040 having a wider area can overlap the electric field formation region.

In another implementation, the protrusions 1021a and 1021b, as illustrated in FIGS. 20 and 21, may have portions that extend in a first direction substantially the same as the lengthwise direction of the first conductive semiconductor layer 2020 and a second direction substantially the same as a widthwise direction of the first conductive semiconductor layer 2020. The protrusions 1021a and 1021b, unlike in FIG. 19, may alternatively protrude from different positions in the extending direction of the pair electrodes 1020a and 1020b. In addition, as illustrated in the drawings, the longer protrusion 1021a may have a structure surrounding the other protrusion 1021b.

At this time, electric fields in different directions (a horizontal direction and a vertical direction based on the drawing) may be formed between the protrusions 1021a and 1021b of the pair electrodes 1020a and 1020b, and the semiconductor light-emitting element 2000 may be seated according to the shape of the protrusions 1021a and 1021b such that both the second conductive electrode 2040 and the first conductive electrode 2030 overlap the electric field formation region. In this case, an assembly inducing force of the electric field can be increased, thereby improving an assembly rate.

On the other hand, the method of manufacturing the display device according to the implementation may further include transferring the semiconductor light-emitting elements 2000 seated at the preset positions of the assembly substrate 1000 to the transfer substrate, and transferring the semiconductor light-emitting elements 2000 transferred to the transfer substrate onto the substrate on which the wiring is disposed.

That is, in order to manufacture the display device according to the implementation, such two additional transfer steps may be further performed in addition to the self-assembling, and the steps may be carried out in the same manner as the transferring of the semiconductor light-emitting elements having the size of several to several tens of µm .

As described above, according to the implementation disclosed herein, the electrodes 2030 and 2040 of the semiconductor light-emitting element 2000 and the electrode 1020 of the assembly substrate 1000 can be manufactured in the asymmetric shape, which can provide an effect of unidirectionally aligning the semiconductor light-emitting elements 2000 having the size of several hundred µm on the assembly substrate 1000 through self-assembly.

In addition, the semiconductor light-emitting elements 2000 can be self-assembled to the assembly substrate 1000 at high speed.

It should be understood that the present disclosure is not limited to the configuration and method of the implementations described above but part or all of the implementations are selectively combined so that various modifications can be made.

1. A display device comprising:
a plurality of semiconductor light-emitting elements; and
a substrate in which the plurality of semiconductor light-emitting elements are accommodated and a wiring is disposed,
wherein the plurality of semiconductor light-emitting elements each includes a sapphire layer on one side, and a plurality of electrodes on another side, the plurality of semiconductor light-emitting elements having an asymmetric shape with respect to at least one direction of the sapphire layer.

2. The display device of claim 1, wherein each of the plurality of semiconductor light-emitting elements comprises:
a first conductive electrode among the plurality of electrodes;
a first conductive semiconductor layer disposed on the sapphire layer and having the first conductive electrode thereon;
an active layer formed on the first conductive semiconductor layer;
a second conductive semiconductor layer formed on the active layer; and
a second conductive electrode among the plurality of electrodes and disposed on the second conductive semiconductor layer to be spaced apart from the first conductive electrode in a horizontal direction.

3. The display device of claim 1, wherein the plurality of electrodes have different size areas.

4. The display device of claim 3, wherein the plurality of electrodes extend in a first direction and a second direction that intersects the first direction, and have different lengths in one of the first direction and the second direction.

5. The display device of claim 2, wherein a thickness from one surface of the sapphire layer on which the first conductive semiconductor layer is formed to another surface of the sapphire layer is thicker than a thickness from the one surface of the sapphire layer on which the first conductive semiconductor layer is formed to the first conductive electrode, and is thicker than a thickness from the one surface of the sapphire layer on which the first conductive semiconductor layer is formed to the second conductive electrode.

6. The display device of claim 1, wherein the plurality of electrodes comprise a magnetic substance.

7. A method for manufacturing a display device, the method comprising:
inserting a plurality of semiconductor light-emitting elements into a chamber containing a fluid;
taking an assembly substrate including assembly electrodes extending in one direction to an assembly position on an upper portion of the chamber; and
seating the plurality of semiconductor light-emitting elements on preset positions of the assembly substrate using a magnetic field and an electric field,
wherein the plurality of semiconductor light-emitting elements each includes a sapphire layer on one side, and a plurality of electrodes on another side, the plurality of semiconductor light-emitting elements having an asymmetric shape with respect to at least one direction of the sapphire substrate.

8. The method of claim 7, wherein the assembly electrodes form pair electrodes that are arranged in pairs, and
wherein the plurality of semiconductor light-emitting elements are seated such that an electrode having at least a larger area of two different electrodes of each semiconductor light-emitting element overlaps the assembly electrodes forming the pair electrodes that arranged in pairs at the same time.

9. The method of claim 7, wherein the sapphire layer has a polarization smaller than that of the fluid in a predetermined electric field frequency range.

10. The method of claim 8, wherein the pair electrodes include protrusions protruding from surfaces facing each other, respectively.

11. The method of claim 10, wherein the protrusions of the assembly electrodes forming the pair electrodes have different protrusion lengths.

12. The method of claim 10, wherein the protrusions include a first portion and a second portion extending in different directions, and
wherein the protrusions alternatively protrude from the assembly electrodes forming the pair electrodes.

13. The method of claim 7, further comprising:
transferring the plurality of semiconductor light-emitting elements seated on the preset positions of the assembly substrate to a transfer substrate; and
transferring the plurality of semiconductor light-emitting elements transferred to the transfer substrate onto a substrate on which wiring is formed.

14. The method of claim 10, wherein the protrusions are separated from each other by a gap, and
wherein the gap is arranged to bisect at least one of the two different electrodes of each semiconductor light-emitting element.

15. The method of claim 14, wherein the gap is arranged to bisect both of the two different electrodes of each semiconductor light-emitting element.

16. The method of claim 15, wherein the gap is arranged to bisect the two different electrodes of each semiconductor light-emitting element in different directions, respectively.

17. A display device comprising:
a wiring substrate;
a plurality of light-emitting elements accommodated on the wiring substrate; and
wirings included in the wiring substrate and connected to the plurality of light-emitting elements,
wherein each semiconductor light-emitting element includes a first side and a second side, and further includes:
a layer on the first side, and a first electrode and a second electrode on the second side, the first electrode being separated from the second electrode and having a size smaller than that of the second electrode.

18. The display device of claim 17, wherein each semiconductor light-emitting element further includes a first conductive semiconductor layer disposed on the layer and having the first electrode and the second electrode located thereon, and
wherein the first electrode being separated from the second electrode exposes an area of the first conductive semiconductor layer.

19. The display device of claim 18, wherein the area of the first conductive semiconductor layer that is exposed has a size greater than the size of the first electrode and less than the size of the second electrode.

20. The display device of claim 17, wherein the layer contains sapphire.
